(19) United States
(12) Patent Application Publication
(10) Pub. No.: US 2001/0041398 A1
(43) Pub. Date: Nov. 15, 2001

(54) Partially removable spacer with salicide formation

(76) Inventors: Paul D. Angello, Wappingers Falls, NY (US); Scott W. Crowder, Ossining, NY (US); Peter Smeys, White Plains, NY (US)

Correspondence Address: McGuire Woods, LLP, Suite 1800, 1750 Tysons Blvd., McLean, VA, 22102-4215, US

(21) Appl. No.: 09/771,697

(22) Filed: Jan. 30, 2001

Related U.S. Application Data
(62) Division of application No. 09/295,134, filed on Apr. 20, 1999.

(51) Int. Cl. H01L 21/336

(52) U.S. Cl. 438/197

(57) ABSTRACT

Formation of sidewalls on a gate structure in layers having a differential etch rate for certain etchants allows metallization and salicide formation annealing of a gate electrode and source/drain regions prior to shallow impurity implantation and impurity activation annealing at the location of a removable portion of a sidewall spacer establishing a gap between source/drain regions and remaining sidewalls of a gate structure. Therefore, diffusion of impurities to a greater depth and impurity deactivation during salacide formation annealing is avoided in a high performance semiconductor device such as a field effect transistor of extremely small dimensions.

### BACKGROUND OF THE INVENTION

1. Field of the Invention

The present invention generally relates to advanced field effect transistors and, more particularly, to manufacturing processes for manufacturing high-performance field effect transistors at extremely small size.

2. Description of the Prior Art

Field effect transistors (FETs), at the present state of the art, are the integrated circuit active switching element of choice for all but the most critical of high density integrated circuit designs. As is recognized in the art, high integration density and extremely small device size provides benefits of improved performance and increased chip functionality as well as manufacturing economies. Small device size and high density provide short signal propagation paths, increasing operational speed while providing more switching devices and circuits on a single chip that can be manufactured by a given set of process steps. At the present state of the art, so-called self-aligned processes are known which allow production of structures included in devices such as sidewalls which also function as implant masks which are well below lithographic resolution limits.

However, the small size of device structures possible at the current state of the art occasionally make known processing steps obsolete or otherwise unacceptable. For example, a shallow impurity implantation is routinely done in a manner self-aligned with sidewalls placed on a gate structure to form a lightly doped drain or similar performance enhancing structure. As part of this process, annealing is generally required following implantation to repair crystal lattice damage due to the implantation and to activate the impurity. This annealing process also causes diffusion of the impurity to a greater depth in the layer or substrate which beneficially reduces the so-called short channel effect. However, the gate connection or contact is preferably formed by a metal silicidation process wherein metal is alloyed with a polysilicon gate deposit in a self-aligned manner (i.e. self-aligned silicide, generally referred to as “salicide”) which also generally requires a further annealing process.

The salicide annealing process can deactivate impurities and cause additional movement or diffusion of the dopant or impurity which may diminish device performance if performed subsequent to the source/drain implant and annealing processes. However, while the selectivity of the salicidation process (i.e. the process proceeds on all exposed silicon surfaces but not on insulators such as silicon nitride and silicon oxide) is generally exploited in semiconductor device construction, the very selectivity of the process does not allow salicidation to precede the implantation process. That is, the implantation process must be done on a bare silicon surface to be adequately controllable and present processes have not provided a practical approach to avoiding salicidation of the locations where the implant is to be performed, when left bare. Further, since salicide or silicide is highly conductive, bridging between the source and/or drain and the gate must be avoided which, at the present state of the art, cannot be achieved if insulative spacers are not present on the gate sidewalls.

It is also known to form laterally layered insulative spacers on the sides of a gate structure. Such a structure could, in theory, mask the shallow drain implant area during the salicidation process and then be removed for the shallow implant. However, in practice, the removal of the second sidewall layer would also remove isolation oxide which is formed between transistors (as well as other structures such as capacitors) and elevate perimeter leakage due to the silicide wrap-around.

Accordingly, it is seen that there is a conflict between a process employing implantation before salicidation which is likely to compromise device performance by the annealing associated with salicidation and a process employing salicidation before implantation which cannot, at the present state of the art, reliably provide an operative device structure, much less a satisfactory manufacturing yield.

### SUMMARY OF THE INVENTION

It is therefore an object of the present invention to provide a high manufacturing yield method for manufacture of a semiconductor field effect transistor in which salicidation precedes source/drain implantation and in which salicidation annealing does not compromise device performance.

It is another object of the invention to provide a field effect transistor structure of extremely small size in which performance is not compromised by the manufacturing process.

In order to accomplish these and other objects of the invention, a method for fabrication of a semiconductor device and a semiconductor device formed by the method are provided wherein the fabrication process includes the steps of forming a composite sidewall on lateral sides of a polysilicon gate structure on a dielectric layer on a substrate, performing self-aligned silicidation on the polysilicon gate structure and portions of the substrate exposed by patterning of the dielectric layer, partially removing the composite sidewall to expose a further area of the substrate, and implanting impurities in the further area of said substrate. This method allows implantation of the impurities to be performed subsequent to the metal deposition and annealing of the silicidation operation and thus maintained at a shallow depth for high performance of the device.

In accordance with another aspect of the invention, a semiconductor device is provided comprising a gate structure, source/drain regions in a semiconductor layer separated from the gate structure by a gap, and an implanted region in the gap between a silicided source/drain region and a sidewall on a silicided gate structure.

### BRIEF DESCRIPTION OF THE DRAWINGS

The foregoing and other objects, aspects and advantages will be better understood from the following detailed description of a preferred embodiment of the invention with reference to the drawings, in which:

FIG. 1A is a cross-sectional view of an early stage in the fabrication of a transistor in accordance with the present invention,

FIG. 1B is a similar cross-sectional view of a stage (corresponding to that of FIG. 1A) in the fabrication of a transistor in accordance with a variant form of the invention and its practice,

FIGS. 2, 3 and 4 are cross-sectional views of intermediate stages in the fabrication of a transistor in accordance with the invention, and

FIG. 5 is a cross-sectional view of a substantially complete transistor in accordance with the invention.

### DETAILED DESCRIPTION OF A PREFERRED EMBODIMENT OF THE INVENTION

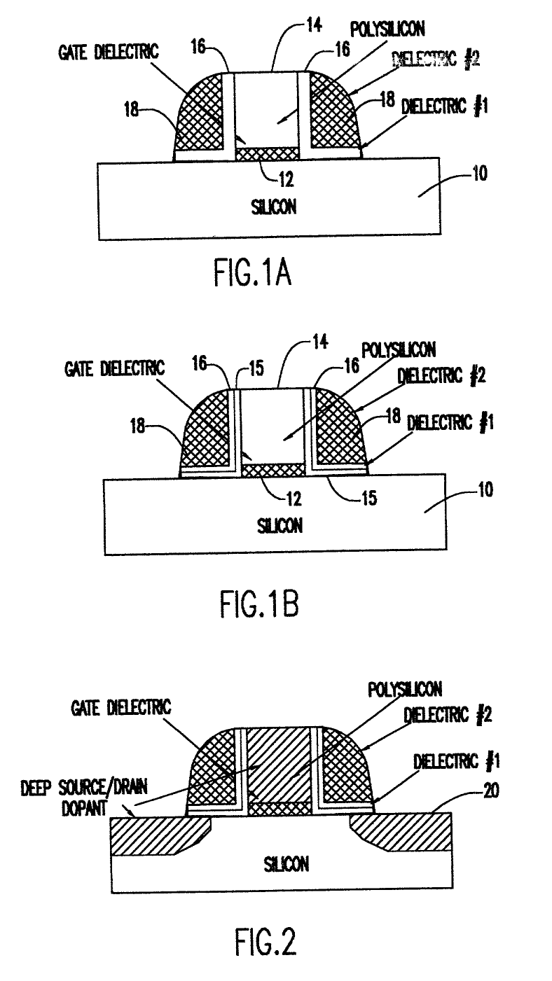

Referring now to the drawings, and more particularly to FIG. 1, there is shown, in cross-sectional form, an early stage in the fabrication of the invention. It is to be understood that none of the Figures are to scale or proportioned to reflect any particular transistor design and that some features not important to the practice of the invention or which are conventional are omitted in the interest of clarity. It is also to be understood that the salient features of the invention are depicted in FIGS. 1-5 in a manner to facilitate an understanding of the principles of the invention by those skilled in the art and in the general form preferred by the inventors at the present time. However, as will be understood by those skilled in the art in view of the following description of the invention, the principles of the invention can be practiced in numerous other forms than that depicted.

To achieve the state shown in FIG. 1, a gate dielectric 12 is first deposited or grown on substrate 10. The gate polysilicon is then deposited on dielectric 12 and etched into patterns defined by a lithographic step. Sidewalls are then sequentially formed on the raised polysilicon gate structure by a well understood process including deposition or growth of a layer followed by anisotropic etching or the like such that the only remaining portions of each layer are on vertical surfaces. It is generally desirable that the sidewall 18 be thicker than sidewall 15 and/or 16 but this relative dimension is not critical to the practice of the invention other than as an incident of the transistor design geometry.

It should be understood that only two sidewalls having different etch rates are necessary for the practice of the invention in accordance with its basic principles. Therefore, while FIG. 1B illustrates three sidewalls 15 (oxide), 16 (nitride) and 18 (oxide) it is preferred that only the nitride and oxide spacers 16, 18 be used, as illustrated in FIG. 1A. The three layered sidewalls of FIG. 1B may provide enhanced dielectric characteristics and in that possible embodiment the nitride layer 16 acts as an etch stop. It would also be possible to deposit like dielectric materials (e.g. oxide) with, for example, different densities to obtain a sufficient differential of etch rate to practice the invention.

It is desirable that dielectric sidewall 16 (and 15, if included) be of a high quality dielectric material since it preferably remains in the completed device and should preferably be of the same material as gate layer 12. However, the material is not critical to the practice of the invention and other material(s) could be employed. Whether or not the materials of sidewalls 16 and gate dielectric 12 are the same, it is important to the suitability of the materials that a differential etch rate or an anisotropic etch process be possible, as will become apparent in the discussion of FIG. 4, below. Sidewalls 15 and 16 form an L-shaped spacer upon which the second/further spacer 18 can be formed. Similarly, the materials of second sidewalls 18 are not at all critical to the practice of the invention other than providing differential etch rates relative to the material of sidewalls 18 and/or sidewalls 15, 16 for some etchants. As noted above, nitride and oxide sidewalls are preferred and suitable etchants are known.

Referring now to FIG. 2 the deep source and drain implants 20 are performed using the gate structure formed as discussed above as a mask. The depth and impurity concentrations are an incident of specific transistors designs and unimportant to the practice of the invention as well as suitable values being generally known to those skilled in the art. This implantation step is followed by annealing which increases the implantation depth while making the impurity concentration more uniform and repairing crystal lattice damage incident to the implantation. The annealing and impurity diffusion during annealing also causes the doped region to extend under a portion of sidewall 18.

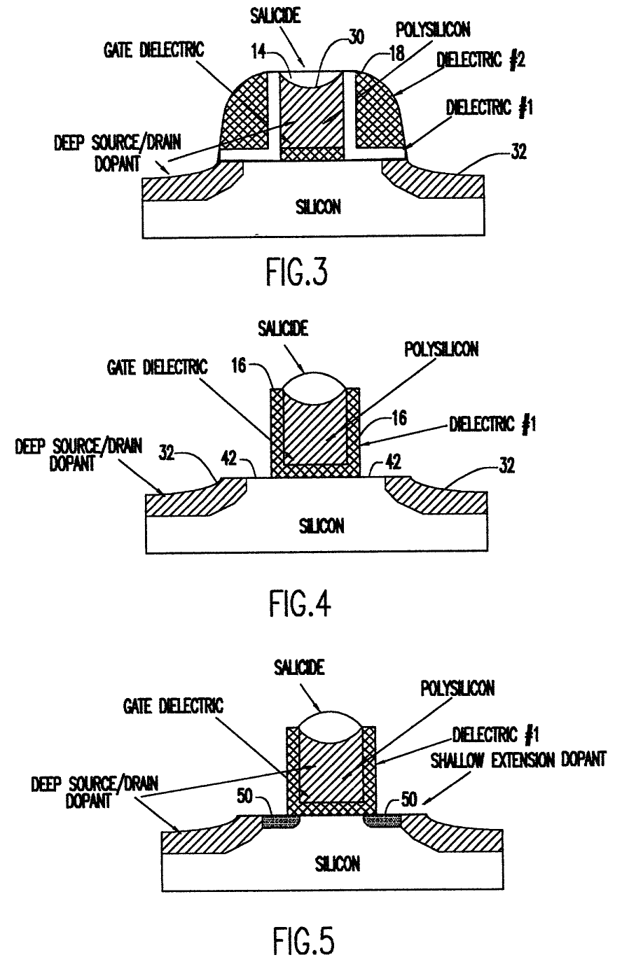

As shown in FIG. 3, salicidation may now be performed in accordance with the invention. Salicidation is performed by deposition of a metal on exposed silicon by sputtering, PVD or other familiar deposition processes and annealing the structure so that the metal (e.g. tungsten) becomes alloyed with a portion of the silicon progressively below the exposed surface until the metal volume is fully incorporated (although the metal distribution in the polysilicon may not be homogeneous. Excess unalloyed metal is removed from the dielectric layer with a differential etch.

The silicidation process generally causes some volume change of the polysilicon since the crystal lattice structure of the grains of silicon and the grains structure, as well. This process can either increase or decrease volume either negligibly or significantly. However, such a volume change in the partially or fully silicided polysilicon body does not affect the principles or practice of the invention and, for convenience, the result of silicidation is depicted as a volume reduction of silicided regions of the silicon substrate and polysilicon gate structure 14, resulting in upwardly concave profiles 30, 32.

Referring now to FIG. 4, the second spacer 18 can be removed by a differential wet or dry isotropic etching process. In any case, it is important that sidewall 16 be left substantially unaffected and, in the sense that, as alluded to above, sidewall 16 (and 15) formed as an L-shaped spacer, removal of second sidewall represents a partial removal of the composite sidewall spacer formed as discussed above. Next, the horizontal leg of sidewall 16 (and 15) is etched using an anisotropic etch which leaves the vertical leg of the sidewall on the polysilicon gate 14 unetched. It should be noted that the resulting structure shown in FIG. 4 exhibits areas 42 of bare silicon exposed by a gap between the silicided substrate regions 32 and remaining sidewalls 16 which are suitable for performing the shallow (LDD) implantations 50 and activation annealing as shown in FIG. 5.

The transistor structure shown in FIG. 5 is substantially complete but for addition of a passivation layer, as and if desired and the attachment of gate, source and drain electrical connections which is facilitated by the salicidation discussed above. It can be appreciated from the foregoing that the above-described fabrication method provides silicidation prior to shallow source/drain implantation which is thus not compromised by silicidation annealing. Isolation structures are not compromised by the sidewall removal because salicidation occurs prior to spacer dielectric removal and a transistor structure having uncompromised electrical performance is provided using a process sequence which is simple and of comparable complexity to current process sequences for formation of transistors which may, in fact, be compromised in performance by the prior manufacturing process.

While the invention has been described in terms of a single preferred embodiment, those skilled in the art will recognize that the invention can be practiced with modification within the spirit and scope of the appended claims.

Having thus described my invention, what I claim as new and desire to secure by Letters Patent is as follows:

1. A method of semiconductor device fabrication including the steps of
forming a composite sidewall on lateral sides of a polysilicon gate structure on a dielectric layer on a substrate,
performing self-aligned silicidation on said polysilicon gate structure and said substrate exposed by patterning of said dielectric layer,
partially removing said composite sidewall to expose a further area of said substrate, and
implanting impurities in said further area of said substrate.

2. A method as recited in claim 1, wherein said step of forming a composite sidewall includes the steps of
forming a layer of nitride, and
forming a layer of oxide over said layer of nitride.

3. A method as recited in claim 1, wherein said step of forming a composite sidewall includes the steps of
forming a layer of oxide of a first density, and
forming a layer of oxide of a second density over said layer of oxide of said first density.

4. A method as recited in claim 1, wherein said step of forming a composite sidewall includes the steps of
forming a layer of oxide,
forming a layer of nitride over said layer of oxide, and
forming a second layer of oxide over said layer of nitride.

5. A semiconductor device comprising
a gate structure,
source/drain regions in a semiconductor layer separated from said gate structure by a gap, and
an implanted region in said gap between a silicided source/drain region and a sidewall on a silicided gate structure.

6. A semiconductor device as recited in claim 5, wherein said gate structure includes a sidewall defining said gap.

7. A semiconductor device as recited in claim 6, wherein said sidewall comprises a layer of oxide.

8. A semiconductor device as recited in claim 6, wherein said sidewall comprises a layer of nitride.

9. A semiconductor device as recited in claim 6, wherein said sidewall comprises a layer of oxide covered by a layer of nitride.

10. A semiconductor device as recited in claim 5, wherein a surface of a gate polysilicon portion of said gate structure and said source/drain region include a silicide layer.

11. A semiconductor device as recited in claim 5, further including a diffused region extending from said implanted region under said gate structure.

12. A semiconductor device formed by a method comprising the steps of
forming a composite sidewall on lateral sides of a polysilicon gate structure on a dielectric layer on a substrate,
performing self-aligned silicidation on said polysilicon gate structure and said substrate exposed by patterning of said dielectric layer,
partially removing said composite sidewall to expose a further area of said substrate, and
implanting impurities in said further area of said substrate.

13. A method as recited in claim 12, wherein said step of forming a composite sidewall includes the steps of
forming a layer of nitride, and
forming a layer of oxide over said layer of nitride.

14. A method as recited in claim 12, wherein said step of forming a composite sidewall includes the steps of
forming a layer of oxide of a first density, and
forming a layer of oxide of a second density over said layer of oxide of said first density.

15. A method as recited in claim 12, wherein said step of forming a composite sidewall includes the steps of
forming a layer of oxide,
forming a layer of nitride over said layer of oxide, and
forming a second layer of oxide over said layer of nitride.
